(19) United States
(12) Patent Application Publication
(10) Pub. No.: US 2012/0273809 A1
(43) Pub. Date: Nov. 1, 2012

(54) LIGHT EMITTING DIODE DEVICE

(75) Inventors: MING-TA TSAI, Hukou (TW); CHING-CHUNG CHEN, Hukou (TW)

(73) Assignee: ADVANCED OPTOELECTRONIC TECHNOLOGY, INC., Hsinchu Hsien (TW)

(21) Appl. No.: 13/441,933

(22) Filed: Apr. 9, 2012

(30) Foreign Application Priority Data
Apr. 27, 2011 (CN) 201110106766.4

(51) Int. Cl. H01L 33/08

(52) U.S. Cl. 257/88; 257/E33.055

(57) ABSTRACT

An LED package includes a substrate, a first LED module and a second LED module. The first LED module includes a plurality of first LEDs arranged at the substrate. The second LED module includes a plurality of second LEDs arranged at the substrate and surrounding the first LED module. A luminous intensity of the first LED module is less than a luminous intensity of the second LED module.

### BACKGROUND

1. Technical Field

The disclosure relates to light emitting diode (LED) devices, and particularly to a light emitting diode device with even distribution of light emission.

2. Description of the Related Art

Light emitting diodes' (LEDs) many advantages, such as high luminosity, low operational voltage, low power consumption, compatibility with integrated circuits, faster switching, long term reliability, and environmental friendliness have promoted their wide use as a lighting source.

The conventional LED device generally includes a plurality of LEDs arranged in an array. However, the intensity of light emitted by the conventional LED device is unevenly distributed; the light intensity dramatically decreases when the radiation angle exceeds 120 degrees. Therefore, the LED device generates a butterfly-type light field or has a radiation angle about 120 degrees only.

Therefore, what is needed is an LED device which can overcome the described limitations.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the present light emitting diode device for microminiaturization. Moreover, in the drawings, like reference numerals designate corresponding parts throughout the views.

FIG. 1 is a top plan view of an LED package in accordance with a first embodiment of the present disclosure.

FIG. 2 is a cross-sectional view of the LED package of FIG. 1, taken along line II-II thereof.

FIG. 3 is a top plan view of an LED package in accordance with a second embodiment of the present disclosure.

FIG. 4 is a top plan view of an LED package in accordance with a third embodiment of the present disclosure.

### DETAILED DESCRIPTION OF EMBODIMENTS

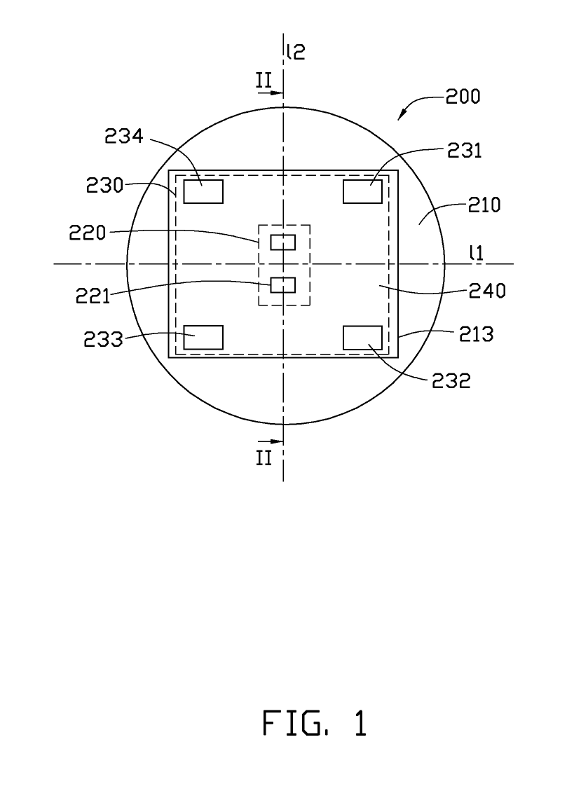

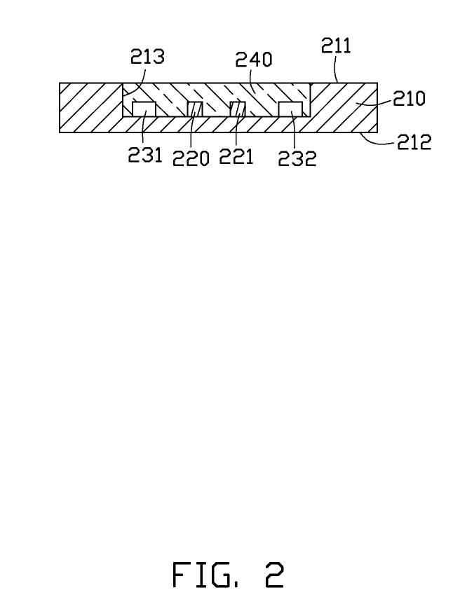

Referring to FIGS. 1 and 2, an LED package 200 in accordance with a first embodiment of the present disclosure is illustrated. The LED package 200 includes a substrate 210, a first LED module 220 and a second LED module 230 arranged in the substrate 210, and an encapsulant 240 covering the first and second LED modules 220, 230.

The substrate 210 has an approximately disc-shaped configuration, and includes a top surface 211 and a bottom surface 212 opposite to the top surface 211. The substrate 210 defines a rectangular cavity 213 in a central portion of the top surface 211, for receiving the first and second LED modules 220, 230 and the encapsulant 240 therein. A first axis of the cavity 213 is indicated as l₁, and a second axis of the cavity 213 is indicated as l₂. The first axis l₁ is perpendicular to the second axis l₂, and intercrosses the second axis l₂ at a center of the cavity 213. The top surface 211 of the substrate 210 in the cavity 213 is planar and has electrical conductive patterns (not shown) formed thereon. The substrate 210 can be made of semiconductor, ceramic or metallic materials. In this embodiment, the substrate 210 is an aluminum-based printed circuit broad, whereby the heat generated by the first and second LED modules 220, 230 can be efficiently transferred to the substrate 210 and dissipated to the environment. An inner surface of the substrate 210 surrounding the cavity 213 can be coated with a reflective layer to improve the light extraction efficiency of the LED package 200. The center of the substrate 210 is coincident with that of the cavity 213.

The first LED module 220 is arranged at a central portion of the top surface 211 of the substrate 210 in the cavity 213, and includes a plurality of first LEDs 221. In the present embodiment, the first LED module 220 includes two first LEDs 221 arranged at two opposite sides of the center of the substrate 210, and centers of the two first LEDs 221 are on the second axis l₂ . In other words, the first LEDs 221 are mirror symmetrical with each other about the first axis l₁. The first LEDs 221 can be surface mounting devices (SMD), and electrodes of the first LEDs 221 are electrically connected to the external power by the conductive patterns on the top surface 211 of the substrate 210 in the cavity 213. The first LEDs 221 connect to each other in series, in parallel or in series-parallel. In the present embodiment, the first LEDs 221 connect to each other in series. The luminous intensity of the first LEDs 221 is represented as A1, the power of the first LED module 220 is represented as W1, and the light emitting surface of the first LED module 220 is represented as S1. In the present embodiment, the power W1 of the first LED module 220 is less than 0.5 watts, and driving current of the first LEDs 221 is less than 150 milli-amperes. It can be understood that the first LED module 220 can be includes only one first LED 221 or more than two first LEDs 221.

The second LED module 230 is arranged at the top surface 211 of the substrate 210 in the cavity 213 and at a periphery of the cavity 213, surrounding the first LED module 220, and includes a plurality of second LEDs 231. In the present embodiment, the second LED module 230 includes four second LEDs 231, 232, 233, 234 respectively arranged at four corners of the top surface 211 of the substrate 210 in the cavity 213. The second LEDs 231 can be surface mounting devices (SMD), and electrodes of the second LEDs 231 are electrically connected to the external power by the conductive patterns on the top surface 211 of the substrate 210 in the cavity 213. The second LEDs 231 connect to each other in series, in parallel or in series-parallel. The luminous intensity of the second LEDs 231 is represented as A2, the power of the second LED module 230 is represented as W2, and the light emitting surface of the second LED module 230 is represented as S2. In the present embodiment, the luminous intensity A2 of the second LED module 230 is larger than the luminous intensity A1 of the first LED module 220. In other words, the power W2 of the second LED module 230 is larger than the power W1 of the first LED module 220, and the light emitting surface S2 of the second LED module 230 is larger than the light emitting surface S1 of the first LED module 220. In the present embodiment, the power W2 of the second LED module 220 is larger than 1 watt, and the driving current of the second LEDs 231 is larger than 300 milli-amperes.

The encapsulant 240 is received in the cavity 213 and covers the first and second LED modules 220, 230. The encapsulant 240 is made of transparent materials, such as silicone, epoxy, quartz, or glass. In this embodiment, a top surface of the encapsulant 240 is substantially coplanar with the top surface 211 of the substrate 210. In this embodiment, phosphor material can be doped into the encapsulant 240 to convert the wavelength of light emitted from the first LEDs 221 and second LEDs 231, 232, 233, 234, to thereby enable the LED package 200 to emit light with a desired color.

In the present embodiment, the first LEDs 221 with lower luminous intensity are arranged at the center of the substrate 210, and the second LEDs 231 with high luminous intensity are arranged at the periphery of cavity 213 of the substrate 210; therefore, the LED package 200 has an even light distribution.

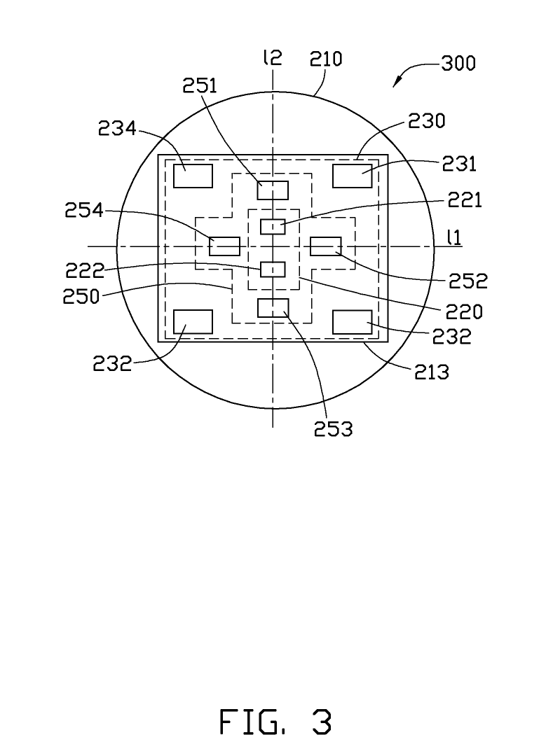

Referring to FIG. 3, an LED package 300 in accordance with a second embodiment of the present disclosure is illustrated. The LED package 300 is similar to the LED package 200 of the first embodiment, and includes a first LED module 220 arranged on a central portion of the substrate 210 and a second LED module 230 arranged at four corners of the cavity 213 of the substrate 210. The center of the substrate 210 is coincident with that of the cavity 213. Differing from the LED package 200, the LED package 300 further includes a third LED module 250 arranged at the top surface of the substrate 210 defining the cavity 213 and located between the first LED module 220 and the second LED module 230.

In the present embodiment, the third LED module 250 includes four third LEDs 251, 252, 253, 254 evenly arranged in the cavity 213. Two of the third LEDs, i.e., third LEDs 251, 253 are arranged on the second axis l₂, and at opposite sides of the first LED module 220. The third LED 251 is mirror symmetrical with the third LED 253 about the first axis l₁. The other two of the third LEDs, i.e., third LEDs 252, 254 are arranged on another two opposite sides of the first LED module 220. The third LEDs 252, 254 are arranged on the first axis l₁, and the third LED 252 is mirror symmetrical with the third LED 254 about the second axis l₂. In the present embodiment, the luminous intensity A3 of the third LED module 250 is larger than the luminous intensity A1 of the first LED module 220, but less than the luminous intensity A2 of the second LED module 230.

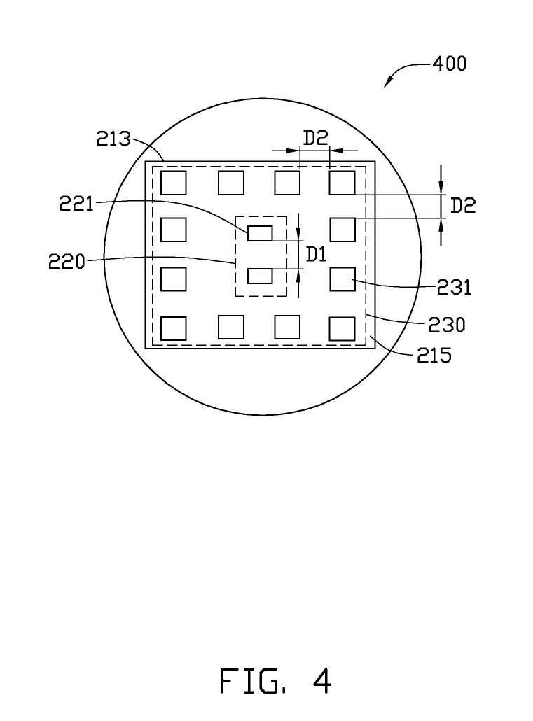

Referring to FIG. 4, an LED package 400 in accordance with a third embodiment of the present disclosure is illustrated. The LED package 400 is similar to the LED package 200 of the first embodiment, and includes a first LED module 220 arranged on a central portion of the substrate 210 and a second LED module 230 surrounding the first LED module 220. The center of the substrate 210 is coincident with that of the cavity 213. The luminous intensity A2 of the second LED module 230 is larger than the luminous intensity A1 of the first LED module 220. Differing from the LED package 200, the second LED module 230 of the LED package 400 includes twelve second LEDs 231 evenly arrayed at a periphery of a top surface 215 of the substrate in the cavity 213. A distance D2 between any two adjacent second LEDs 231 is equivalent to each other. A distance D1 between the two first LEDs 221 is larger than the distance D2. In this embodiment, the first LED module 220 which is located at the central portion of the substrate 210 has a lower density of LED than that of the second LED module 230 which is located at the periphery of the top surface 215 of the substrate in the cavity 213. Thus, light emission of the LED package 400 has an even distribution via the arrangement of the first LED module 220 and the second LED module 230.

It can be understood for a skilled one in the related art that an amount of the first LEDs, second LEDs, and the third LEDs can be adjusted according to an actual demand regarding the required brightness of the LED package 200, 300, 400.

It is to be further understood that even though numerous characteristics and advantages have been set forth in the foregoing description of embodiments, together with details of the structures and functions of the embodiments, the disclosure is illustrative only; and that changes may be made in detail, especially in matters of shape, size, and arrangement of parts within the principles of the disclosure to the full extent indicated by the broad general meaning of the terms in which the appended claims are expressed.

What is claimed is:

1. A light emitting diode (LED) package, comprising:
a substrate;
a first LED module comprising a plurality of first LEDs arranged at the substrate; and
a second LED module comprising a plurality of second LEDs arranged at the substrate and surrounding the first LED module, a luminous intensity of the first LED module being less than a luminous intensity of the second LED module.

2. The LED package of claim 1, wherein a power of the first LED module is less than that of the second LED module.

3. The LED package of claim 1, wherein a light emitting surface of the first LED module is less than that of the second LED module.

4. The LED package of claim 1, wherein the substrate has a top surface defining a cavity therein, the first LED module and the second LED module being arranged on the top surface of the substrate defining the cavity.

5. The LED package of claim 4, wherein the first LEDs are arranged at a central portion of the top surface of the substrate in the cavity, and the second LEDs are evenly arranged at a periphery of the cavity.

6. The LED package of claim 5, wherein a distance between two adjacent second LEDs is less than a distance between two adjacent first LEDs.

7. The LED package of claim 1, further comprising a third LED module arranged at the substrate and located between the first LED module and the second LED module.

8. The LED package of claim 7, wherein the third LED module comprises a plurality of third LEDs evenly distributed on the substrate.

9. The LED package of claim 7, wherein a luminous intensity of the third LED module is larger than the luminous intensity of the first LED module, and less than the luminous intensity of the second LED module.

10. An LED package, comprising:
a substrate defining a cavity in a top surface thereof;
a first LED module comprising a plurality of first LEDs arranged at a central portion of the top surface of the substrate in the cavity; and
a second LED module comprising a plurality of second LEDs arranged at the top surface of the substrate in the cavity and at a periphery of the cavity, a luminous intensity of the first LED module being less than that of the second LED module.

11. The LED package of claim 10, wherein a distance between two adjacent second LEDs is less than a distance between two adjacent first LEDs.

12. The LED package of claim 11, wherein the distance between any two adjacent second LEDs is equivalent to each other.

13. The LED package of claim 10, further comprising a third LED module arranged at the top surface of the substrate in the cavity and located between the first LED module and the second LED module.

14. The LED package of claim 13, wherein a luminous intensity of the third LED module is larger than the luminous intensity of the first LED module, and less than the luminous intensity of the second LED module.

15. An LED package, comprising:
a substrate;
a first LED module comprising a plurality of first LEDs arranged at a central portion of the substrate;
a second LED module comprising a plurality of second LEDs arranged at a periphery of the substrate; and
a third LED module comprising a plurality of third LEDs arranged at the substrate and located between the first LED module and the second LED module;
wherein a luminous intensity of the third LED module is larger than a luminous intensity of the first LED module, and less than a luminous intensity of the second LED module.
